(19) United States
(12) Patent Application Publication
(10) Pub. No.: US 2004/0005735 A1
(43) Pub. Date: Jan. 8, 2004

(54) Dicing method for micro electro mechanical system chip

(75) Inventors: Joon Seok Kang, Suwon-Shi (KR); Sung Cheon Jung, Suwon-Shi (KR); Sang Kee Yoon, Suwon-Shi (KR); Hyun Kee Lee, Suwon-Shi (KR)

Correspondence Address: DARBY & DARBY P.C., 805 Third Avenue, New York, NY, 10022, US

(73) Assignee: SAMSUNG ELECTRO-MECHANICS CO., LTD., Suwon-Shi (KR)

(21) Appl. No.: 10/412,486

(22) Filed: Apr. 11, 2003

(30) Foreign Application Priority Data
Jul. 5, 2002 (KR) 2002-38792

(51) Int. Cl. H01L 21/44; H01L 21/50; H01L 21/301; H01L 21/78

(52) U.S. Cl. 438/113; 438/460; 438/465; 438/114

(57) ABSTRACT

A dicing method for a micro electro mechanical system chip, in which a high yield and productivity of chips can be accomplished, resulting from preventing damage to microstructures during a dicing process by using a photoresist or filler. The dicing method comprises the steps of spraying a liquid photoresist as a protectant of microstructures on a wafer on which the microstructures are installed, and coating the whole surface of the wafer with the photoresist (first step); heat treating the coated wafer at a predetermined temperature for a certain time to remove residual water in the sprayed photoresist and to cure the sprayed photoresist (second step); dicing the heat treated wafer (third step); and removing the photoresist (fourth step).

### BACKGROUND OF THE INVENTION

1. Field of the Invention

The present invention relates to a dicing method for a micro electro mechanical system chip, and more particularly to a dicing method for a micro electro mechanical system chip, in which a high yield and productivity of chips can be accomplished, resulting from preventing damage to microstructures during a dicing process by using a photoresist or filler.

2. Description of the Related Art

Generally, the information society of the 21^{st} century demands the recognition of the peripheral information, utilizing many sensors to measure/analyze in real time. As recent industries follow an information/electronic trend, there is growing demand for sensors to detect physical properties such as pressure, temperature, and speed and chemical properties.

Unfortunately, the current sensors as components have size limitations, quality limitations in terms of function, performance and reliability, and cost reduction limitations. The technology that can overcome these limitations is a high integrated micro sensors-on-chip using Micro Electro-Mechanical System (hereinafter, MEMS).

MEMS sensors, manufactured through semiconductor batch processes, can be integrated with signal process circuits on a single chip by on-chip integration, have functions such as self diagnosis, computation and digital signal output, as well as have low cost, high reliability, and micro packaging characteristics. The high integrated micro sensors-on-chip is an integrated micro multi-sensing system that incorporates several MEMS sensors and signal process circuits on a silicon chip. It acts as an information gathering center. The information gathering center gathers and analyzes peripheral information such as physical properties (pressure, speed, position, attitude etc.) and chemical properties, and outputs the needed information.

General MEMS techniques are advantageous in development of low cost, high performance microelements. Therefore, applications to inertial sensors, pressure sensors, biomedical elements and optical communication components have been actively studied.

MEMS-based variable optical attenuators (VOA) and optical switches (OSW) are kinds of optical communication components, in which a barrier and an actuator fabricated by bulk micro machining technology serve to attenuate the quantity of light and switch an optical path between two optical fibers, i.e., a transmitter optical fiber and a receiver optical fiber aligned on a chip in a straight line. Like the MEMS VOA, precise alignment of optical fibers on a chip is important in optical MEMS elements. Therefore, the optical MEMS elements require high aspect ratio structures to ensure precise alignment between optical fiber core and chip structures.

FIG. 1 is a cross sectional view of conventional high aspect ratio MEMS structures and FIG. 2 is a microphotograph of MEMS structures damaged during a dicing process.

In a conventional semiconductor manufacturing process, there are no MEMS microstructures on the surface of a wafer. In this respect, the wafer is mounted on a guide ring, sprayed with cooling water and diced during a high-speed rotation of a dicing blade.

In the case where a dicing method used in a conventional semiconductor manufacturing process is applied to optical MEMS structures requiring high aspect ratio structures as shown in FIG. 1, the structures are liable to be damaged due to water pressure of cooling water required for absorbing heat generated during dicing, and air currents generated about a high-speed rotating dicing blade, as shown in FIG. 2.

To solve the above problems, general inertial MEMS elements are packaged with a glass wafer before dicing to thereby protect microstructures.

However, optical MEMS elements require direct alignment with optical fibers on a chip and thus the above dicing method following packaging with a glass wafer cannot be applied. Therefore, microstructures are directly exposed to cooling water and air currents during dicing and thus readily damaged. As a result, the yield of chips is undesirably lowered.

### SUMMARY OF THE INVENTION

Therefore, the present invention has been made in view of the above problems, and it is an object of the present invention to provide a dicing method for a micro electro mechanical system chip, and more particularly to a dicing method for a micro electro mechanical system chip, in which a high yield and productivity of chips can be accomplished, resulting from preventing damage to microstructures during a dicing process by using a photoresist or filler.

In accordance with one aspect of the present invention, the above object and other objects can be accomplished by the provision of a dicing method for a micro electro mechanical system chip, comprising the steps of spraying a liquid photoresist as a protectant of microstructures on a wafer on which the microstructures are installed, and coating the whole surface of the wafer with the photoresist (first step); heat treating the coated wafer at a predetermined temperature for a certain time to remove residual water in the sprayed photoresist and to cure the sprayed photoresist (second step); dicing the heat treated wafer (third step); and removing the photoresist (fourth step).

Preferably, the heat treatment in the second step may be carried out in a stepwise manner under varying time and temperature conditions to prevent damage to microstructures caused by expansion of air bubbles in the photoresist due to a sudden temperature change.

Further preferably, the removing of the photoresist in the fourth step may be carried out using a solvent such as acetone or non-acetone remover depending on the type of the photoresist and heat treatment condition, followed by IPA/DI cleaning.

In accordance with another aspect of the present invention, there is provided a dicing method for a micro electro mechanical system chip, comprising the steps of repeatedly spraying a liquid filler as a protectant of microstructures on the whole surface of a wafer on which the microstructures are installed and curing the sprayed filler to completely fill the whole surface of the wafer with the filler (first step); dicing the wafer (second step); and removing the filler (third step).

Preferably, the filler may be an acrylic resin based filler.

Further preferably, the third step may comprise the steps of removing the filler by immersing diced chips in a solvent like acetone and then removing the residual filler and solvent by immersing the chips in room temperature IPA or boiling IPA.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross sectional view of high aspect ratio MEMS structures;

FIG. 2 is a microphotograph of MEMS structures damaged during a dicing process;

FIG. 3 is a cross sectional view of a conventional optical MEMS wafer prior to a dicing process;

FIG. 4 is a cross sectional view of a photoresist-coated MEMS wafer according to one embodiment of the present invention;

FIG. 5 illustrates a dicing process according to one embodiment of the present invention;

FIG. 6 is a cross sectional view of a photoresist-removed wafer according to one embodiment of the present invention;

FIG. 7 is a cross sectional view of a primary filler-filled and cured wafer according to another embodiment of the present invention;

FIG. 8 is a cross sectional view of a secondary filler-filled and cured wafer according to another embodiment of the present invention;

FIG. 9 is a cross sectional view of a final filler-filled and cured wafer according to another embodiment of the present invention;

FIG. 10 illustrates a dicing process according to another embodiment of the present invention;

FIG. 11 is a cross sectional view of a filler-removed wafer;

FIG. 12 is a microphotograph of microstructures after a filler is completely filled and cured; and

FIG. 13 is a microphotograph of a chip after a dicing process and cleaning process.

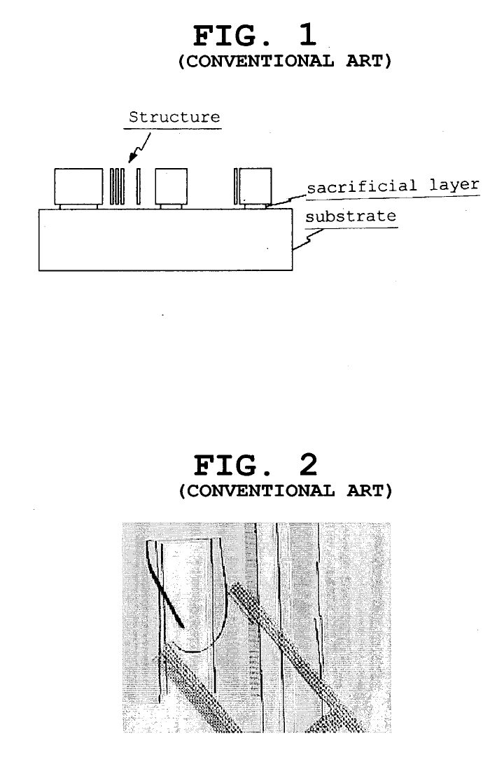

### DESCRIPTION OF THE PREFERRED EMBODIMENTS

Hereinafter, one preferable embodiment of the present invention will be described in more detail by way of the accompanying figures.

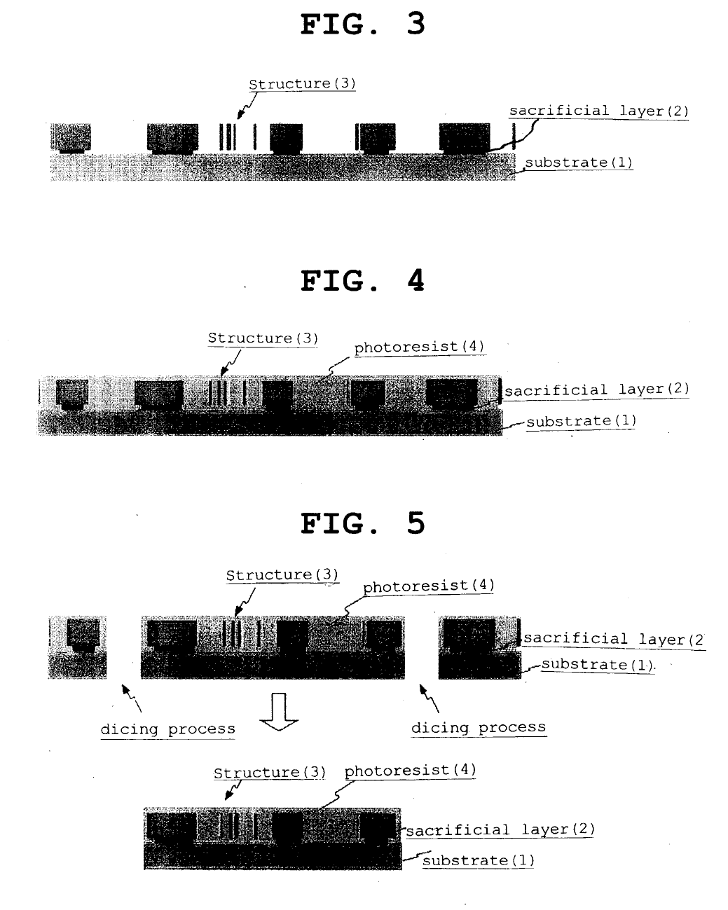

FIGS. 3 to 6 show a dicing process for a MEMS chip of the present invention. In detail, FIG. 3 is a cross sectional view of a conventional optical MEMS wafer prior to a dicing process and FIG. 4 is a cross sectional view of a photoresist-coated MEMS wafer according to the present invention. FIG. 5 illustrates a dicing process according to the present invention and FIG. 6 is a cross sectional view of a photoresist-removed wafer according to the present invention.

Next, a dicing method for a MEMS chip will be described with reference to FIGS. 3 to 6.

Referring to FIGS. 3 and 4, a liquid photoresist 4 is sprayed on a substrate 1 on which microstructures 3 are installed. Then, the whole surface of the substrate 1 is coated with the photoresist 4 by operating a spin coater at a predetermined speed for a certain time.

In this case, in order to uniformly coat the whole surface of the structures 3, the photoresist 4 is selected depending on the height and shape of the structures 3 while taking into consideration the viscosity of the photoresist. A coating condition such as a coating speed and time is determined depending on the type of the photoresist 4.

After coating of the photoresist 4, heat treatment is carried out at a predetermined temperature for a certain time to remove residual water in the photoresist 4 and cure the photoresist. At this time, in the case wherein heat treatment of the photoresist 4 is carried out under a sudden temperature change, damage to the structures 3 is caused by expansion of air bubbles in the photoresist 4. Therefore, it is preferable for the heat treatment to be carried out in a stepwise manner under varying time and temperature conditions.

After the structures are protected with the photoresist according to the above process, a dicing process is carried out according to the general procedure as shown in FIG. 5. Then, the photoresist 4 utilized as a protectant of the structures 3 is removed as shown in FIG. 6.

The removal process of the photoresist 4 is carried out using a solvent such as acetone or non-acetone remover depending on the type of the photoresist 4 and heat treatment condition, followed by IPA/DI cleaning.

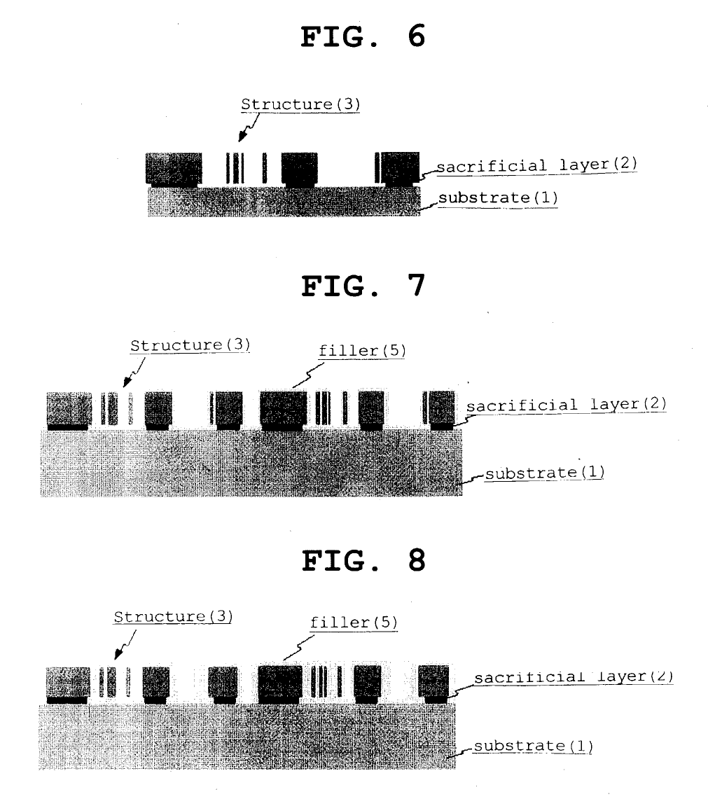

In accordance with another embodiment of the present invention, a dicing method for a MEMS chip using a filler instead of the photoresist is provided as shown in FIGS. 7 to 11.

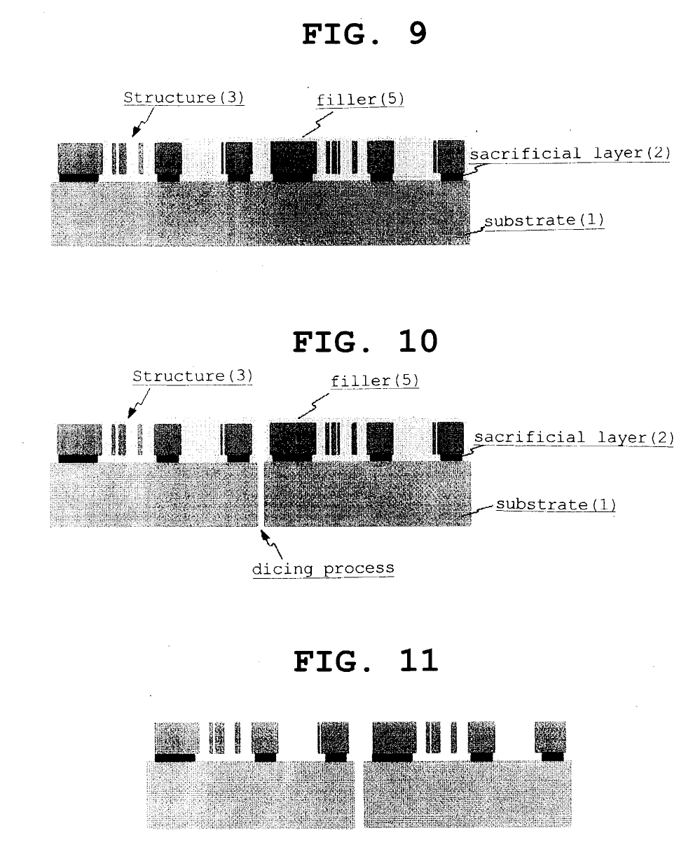

FIG. 7 is a cross sectional view of a primary filler-filled and cured wafer according to the present invention, FIG. 8 is a cross sectional view of a secondary filler-filled and cured wafer according to the present invention and FIG. 9 is a cross sectional view of a final filler-filled and cured wafer according to the present invention. FIG. 10 illustrates a dicing process according to the present invention and FIG. 11 is a cross sectional view of a filler-removed wafer.

Because another embodiment of the present invention as shown in FIGS. 7 to 11 is similar to one embodiment as shown in FIGS. 3 to 6, a repetitive detailed description thereof will be omitted.

No particular limitation is imposed on the filler 5. However, it is most preferable to use an acrylic resin based filler in the embodiment of the present invention.

As shown in FIGS. 7 to 9, the reason why the filler 5 is repeatedly uniformly sprayed and cured on a substrate 1 is to completely fill the space between microstructures 3 with the filler 5. After the filler is sufficiently filled in a desired thickness and cured, a dicing process is carried out as shown in FIG. 10.

The diced chips are removed of the filler 5 in a solvent such as acetone. Then, the diced chips are immersed in room temperature IPA or boiling IPA to thereby remove the residual filler and solvent and prevent binding between MEMS microstructures.

Consequently, according to the present invention, an optical MEMS wafer is coated with a photoresist or filler to thereby protect microstructures, and then the wafer is diced, so that damage to the microstructures caused by an external pressure during dicing is prevented.

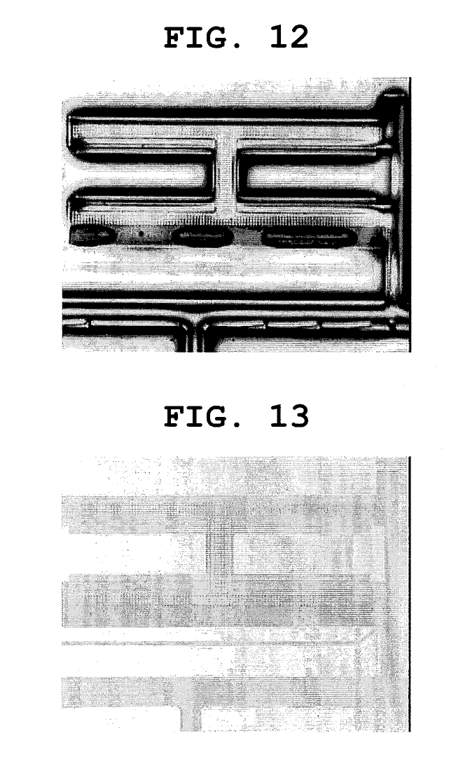

The effect of the embodiment of the present invention using a filler can be appreciated from the accompanying FIGS. 12 and 13.

FIG. 12 is a microphotograph of microstructures after a filler is completely filled and cured and FIG. 13 is a microphotograph of a chip after a dicing process and cleaning process.

Comparing the microphotograph of FIG. 13 with that of FIG. 2 after a dicing process, it can be apparently seen that damage to microstructures can be prevented by using a filler prior to a dicing process in accordance with the present invention.

As apparent from the above description, the present invention provides a dicing method for a micro electro mechanical system chip, in which the use of a photoresist or filler makes it possible to prevent damage to microstructures, resulting in reducing a defective ratio in manufacturing optical MEMS products such as VOA and OSW requiring high aspect ratio (HAR) structures, improving the yield of the products, and contributing to mass production of MEMS products.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A dicing method for a micro electro mechanical system chip, comprising the steps of:
spraying a liquid photoresist as a protectant of microstructures on a wafer on which the microstructures are installed, and coating the whole surface of the wafer with the photoresist (first step);
heat treating the coated wafer at a predetermined temperature for a certain time to remove residual water in the sprayed photoresist and to cure the sprayed photoresist (second step);
dicing the heat treated wafer (third step); and
removing the photoresist (fourth step).

2. The dicing method as set forth in claim 1, wherein the heat treatment in the second step is carried out in a stepwise manner under varying time and temperature conditions to prevent damage to microstructures caused by expansion of air bubbles in the photoresist due to a sudden temperature change.

3. The dicing method as set forth in claim 1, wherein the removing of the photoresist in the fourth step is carried out using a solvent such as acetone or non-acetone remover depending on the type of the photoresist and heat treatment condition, followed by IPA/DI cleaning.

4. A dicing method for a micro electro mechanical system chip, comprising the steps of:
repeatedly spraying a liquid filler as a protectant of microstructures on the whole surface of a wafer on which the microstructures are installed and curing the sprayed filler to completely fill the whole surface of the wafer with the filler (first step);
dicing the wafer (second step); and
removing the filler (third step).

5. The dicing method as set forth in claim 4, wherein the filler is an acrylic resin based filler.

6. The dicing method as set forth in claim 4, wherein the third step comprises the steps of removing the filler by immersing diced chips in a solvent like acetone and then removing the residual filler and solvent by immersing the chips in room temperature IPA or boiling IPA.
